(19) United States
(12) Patent Application Publication
(10) Pub. No.: US 2006/0243974 A1
(43) Pub. Date: Nov. 2, 2006

(54) Thin-film transistor

(76) Inventors: Keng-Li Su, Hsinchu (TW); Chen-Pang Kung, Hsinchu (TW); Jan-Ruei Lin, Hsinchu (TW); Chia-Pao Chang, Hsinchu (TW); Yi-Hsun Huang, Hsinchu (TW)

Correspondence Address: HARNESS, DICKEY & PIERCE, P.L.C., P.O. BOX 8910, RESTON, VA, 20195, US

(21) Appl. No.: 11/175,440

(22) Filed: Jul. 7, 2005

(30) Foreign Application Priority Data
Apr. 29, 2005 (TW) 94114041

(51) Int. Cl. H01L 29/04

(52) U.S. Cl. 257/49

(57) ABSTRACT

A thin-film transistor (TFT) is described to have a gate layer, an insulating layer, a semiconductor layer, and a source/drain layer formed on a flexible substrate. The source and the drain layers are separated by a channel with a special shape. This does not only increase the aspect ratio of the channel per unit area, the source and the drain also have multiple directions for transmitting carriers. The carrier mobility of the TFT is thus enhanced with uniform and stable circuit properties.

### BACKGROUND OF THE INVENTION

1. Field of Invention

The invention relates to a TFT and, in particular, to a TFT with a special structure.

2. Related Art

The active layer of the TFT is made of semiconductor materials to increase the carrier mobility. Therefore, they have been widely used in circuits of various functions. However, the active layer has grains of different sizes. Such intrinsic defects will reduce the carrier mobility. Moreover, the TFT itself requires a higher working voltage. For example, the carrier mobility of an α-Si TFT is between 0.5 cm²/V.S and 1 cm²/V.S, whereas that of a poly-Si TFT is between 30 cm²/V.S and 300 cm²/V.S

Under the restriction of lower carrier mobility due to the above-mentioned intrinsic defects, it is necessary to have a sufficiently large driving current to charge pixel capacities. This can only be achieved by increasing the aspect ratio, W/L, of the channel. However, one then faces such problems as increasing area and lower aperture rate. The gate-drain and gate-source interfaces of the TFT are working under a huge electric field. Therefore, the kink effect is likely to occur. This in turn will result in the problems of a shorter lifetime and functioning instability.

There are two solutions to improve the intrinsic defects of the TFT. One is to improve the manufacturing process. This is a big engineering problem that requires a huge amount of manpower, time, and capital. The other is to change the structure of the TFT. As shown in FIG. 1, the conventional TFT has a structure with a gate 10, a source 20, and a drain 30. A rectangular channel 40 is formed between the source 20 and the drain 30. It occupies a larger area when the channel aspect ratio is fixed. This needs to be improved. Moreover, as shown in FIGS. 2A and 2B, the conventional TFT has a low architecture deflection in the vertical and horizontal directions. Therefore, it is not suitable for flexible circuits. Also, as shown in FIGS. 3A to 3D, the process control migration is small. Once there is any deviation in the process, the electrical performance will be bad. As shown in FIG. 4, the structure of the conventional TFT is likely to be locally over-heated; that is, heat concern of hot spots a-d will be generated. In the future, the substrate in the TFT process can be changed from the current rigid substrate to the flexible substrate, so that it is more convenient to carry and use. Therefore, the TFT itself has to be flexible too, and the element characters are not to be seriously changed or damaged by the deflection of the substrate. The conventional TFT structure is totally unsuitable for the above purposes. Therefore, it is imperative to provide a new TFT to solve these problems.

### SUMMARY OF THE INVENTION

In view of the foregoing, an object of the invention is to provide a TFT which, through a special structure design, can avoid the undesired effects due to its intrinsic defects and the electrical property changes due to the deflection of the substrate.

To achieve the above object, the disclosed TFT is formed with a source/drain layer, a gate layer, an insulating layer, a semiconductor layer, and a flexible substrate. The source/drain layer, the gate layer, the insulating layer, and the semiconductor layer are formed on the flexible substrate. The source/drain layer contains a source, a drain, and a channel. The channel encloses and defines a peninsula region with one open end. One of the source and the drain is located inside the peninsula region, while the other is outside the channel. The source and the drain have two or more transmission directions. The gate layer is provided in the direction perpendicular to the channel of the source/drain layer. The insulating layer is then used to separate the source/drain layer and the gate layer. The semiconductor layer is connected to the source/drain layer and the insulating layer.

Moreover, another TFT disclosed herein is formed with a source/drain layer, a semiconductor layer, an insulating layer, a gate layer, and a flexible substrate. The source/drain layer, the gate layer, the insulating layer, and the semiconductor layer are formed on the flexible substrate. The source/drain layer contains a source, a drain, and a channel. The channel encloses and defines an island region, which is a closed region. One of the source and the drain is located inside the island region, while the other is outside the channel. The source and the drain have two or more transmission directions. The gate layer is provided in the direction perpendicular to the channel of the source/drain layer. The insulating layer is then used to separate the source/drain layer and the gate layer. The semiconductor layer is connected to the source/drain layer and the insulating layer.

The disclosed TFT with the above-mentioned structure does not only have a higher channel area per unit area, such a channel design also increases the transmission directions of the carriers between the source and the drain. Therefore, the disclosed TFT has such advantages as a lower grain boundary trap effect, higher carrier mobility, a more uniform current, a higher driving capability, and reducing the field and kink effects.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow illustration only, and thus are not limitative of the present invention, and wherein:

FIG. 1 is a schematic top view of the conventional TFT structure;

FIGS. 2A and 2B show respectively the deflection of the conventional TFT in the vertical and horizontal directions;

FIGS. 3A to 3D show respectively the situations that a conventional TFT is deflected to the left, right, up, and down;

FIG. 4 shows that a conventional TFT is locally over-heated;

FIGS. 5A and 5B are schematic cross-sectional and top views of the TFT in a first embodiment of the invention;

FIGS. 6A to 6C schematically show the source/drain layer with different shapes of channels according to the first embodiment;

FIGS. 7A and 7B show respectively the TFT with different areas of gate layers in the first embodiment, where each gate layer has an opening region;

FIG. 8 is a schematic top view of the TFT in a second embodiment of the invention;

FIGS. 9A and 9B are schematic views of the source/drain layer with different shapes of channels in the second embodiment;

FIGS. 10A and 10B are schematic views of the TFT's with different areas of gate layers in the second embodiment, where each gate layer has an opening region;

FIG. 11 is a schematic view of using the TFT in FIG. 7B as the switch of pixels in the panel;

FIGS. 12A and 12B show that the TFT of FIG. 7B is deflected in the vertical and horizontal directions, respectively;

FIGS. 13A to 13D show that the TFT in FIG. 7B is deviated respectively to the left, right, up and down;

FIG. 14 shows the current distribution in the TFT of FIG. 7B; and

FIGS. 15A to 15C show the cross-sectional views of coplanar, inverted coplanar, and staggered TFT's in FIG. 7B.

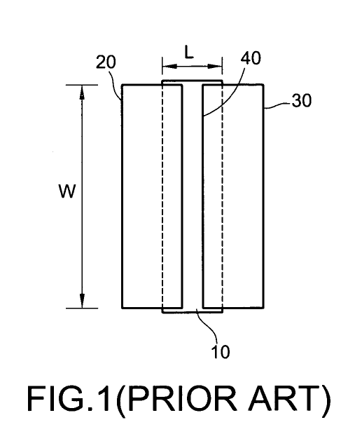

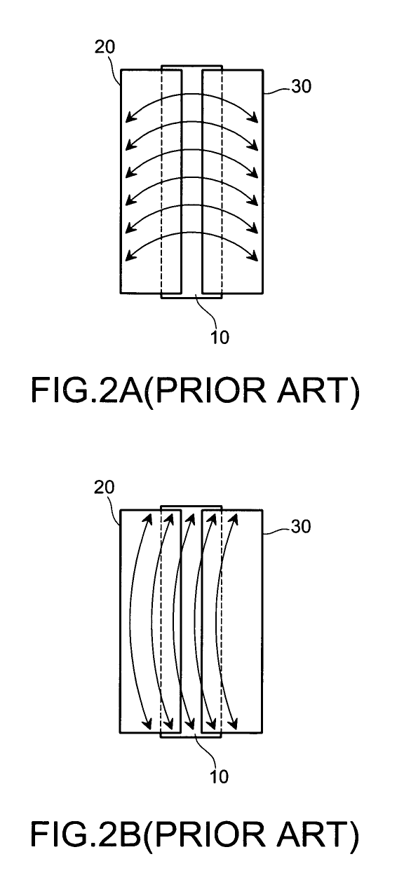

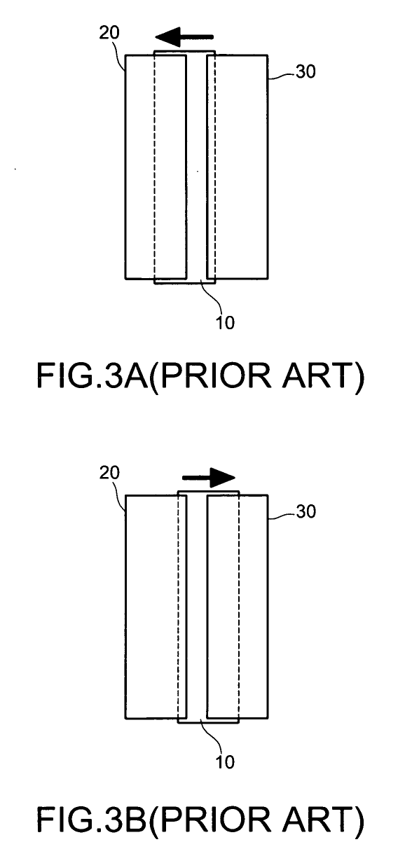

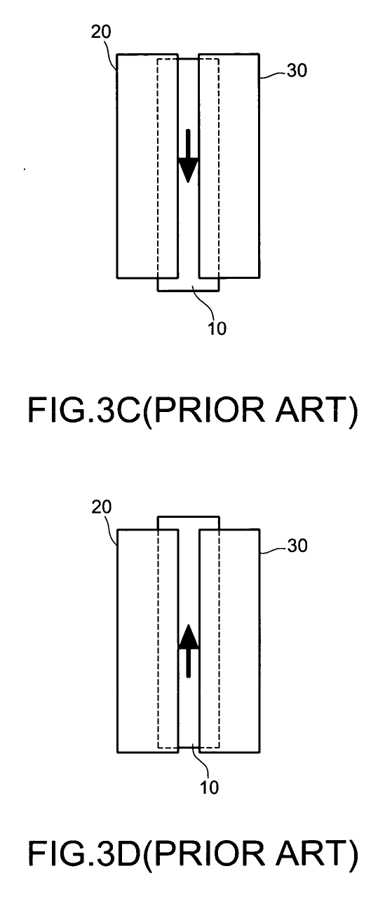

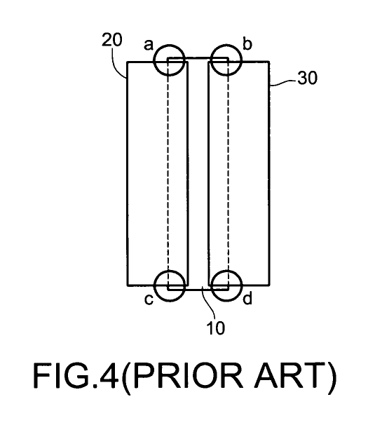

### DETAILED DESCRIPTION OF THE INVENTION

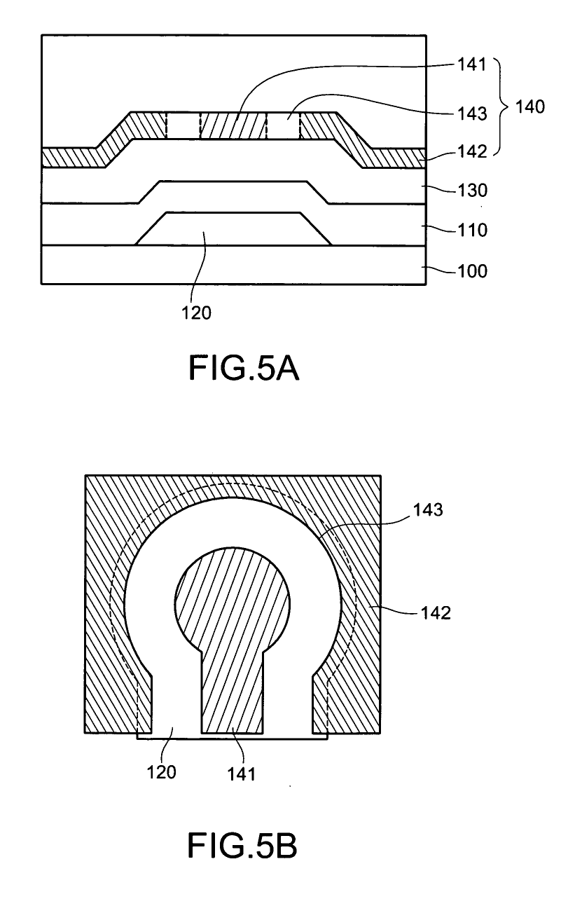

FIGS. 5A and 5B are the cross-sectional and top views of the TFT according to a first embodiment of the invention. The TFT is an inverter staggered TFT of the bottom gate type. The flexible substrate 100 is formed with a gate layer 120. An insulating layer 110 is formed on the gate layer 120 to provide insulation. The α-Si semiconductor layer 130 is formed on the gate layer 120 and the insulating layer 110. The source/drain layer 140 is formed on the semiconductor layer 130. Besides, the disclosed TFT further contains an Ohmic contact layer between the semiconductor layer and the source/drain layer in practice. The Ohmic contact layer is the adhesive layer between the semiconductor layer and the source/drain layer, forming an Ohmic contact in between. The source/drain layer 140 contains a source 141, a drain 142, and a channel 143. The source 141 and the drain 142 are formed inside and outside a channel 143. The channel 143 is comprised of an annular band and two non-annular regions. A peninsula region is enclosed and defined on the inner side. The peninsula region is a half-closed region with one open end. The source 141 is located inside the peninsula region. Therefore, the structure has a round head and a neck. The gate layer 120 has a shape similar to the source 141, also with a round head and a neck. However, its area is larger than the source 141. The drain 142 is provided along the outer side of the channel 143. Since the carrier transmission between the source 141 and the drain 142 uses the path of the semiconductor layer 130 under the channel 143, there are multiple carrier transmission directions between the source 141 and the drain 142 in this embodiment.

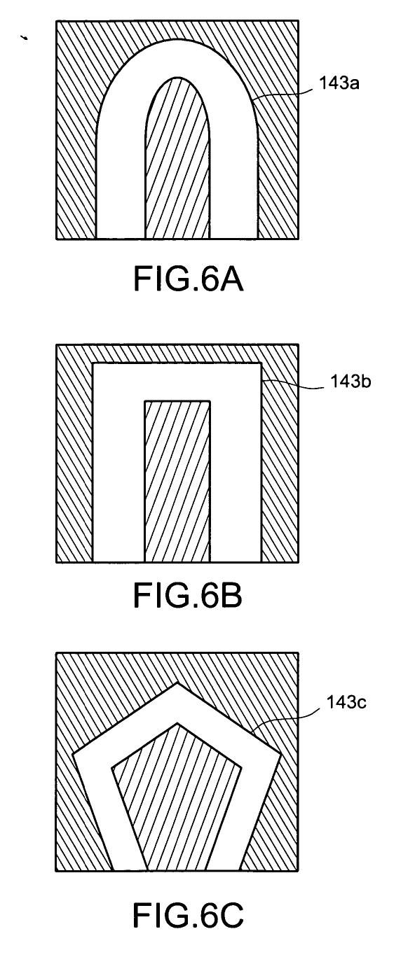

In this embodiment, the channel 143 includes an annular band and two non-annular regions so that the source 141 has the shapes of a round head and a neck. The drain 142 has concave arcs. The shape of the gate layer 120 is similar to the source 141. However, the invention is not limited to this. Moreover, the source 141 and the drain 142 can be provided respectively along the inner and outer sides of the channel 143 or along the outer and inner sides, respectively. Since the source 141 and the drain 142 are separated by the channel 143, the shapes of the source 141 and the drain 142 need to match the shape of the channel 143. In this embodiment, the shape of the channel 143 is so to enclose a peninsula region. The shape of the source 141 also has a peninsula shape. As shown in FIGS. 6A to 6C, the peninsula regions defined by the channels 143a, 143b, 143c are roughly in the shapes of a U, a rectangle, and a polygon.

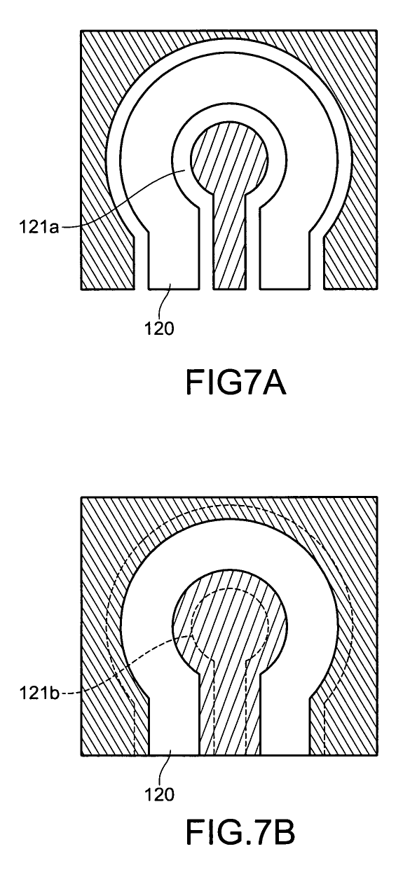

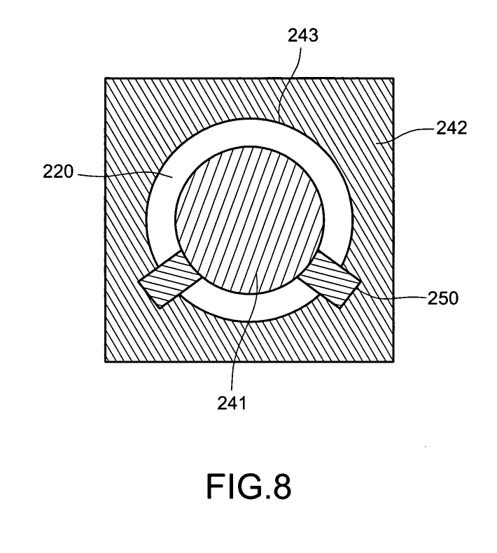

The profile of the gate layer 120 corresponds to that of the peninsula region. The area of the gate layer 120 can be either smaller or bigger than the peninsula region. Alternatively, as shown in FIGS. 7A and 7B, the gate layer 120 has an opening region 121a or 121b. Their shapes correspond to the peninsula region. The area of the opening region 121a or 121b can be smaller (FIG. 7A) or bigger (FIG. 7B) than the peninsula region.

As shown in FIG. 8, the channel 243 in the second embodiment of the invention has an annular band, whose inner side defines a closed island region. The source 241 is circular, and so is the gate layer 220. This structure enables more transmission directions between the source 241 and the drain 242, achieving almost omni-directional. A higher current stability is achieved. In particular, the source 241 is provided with a wire 250 for electrically connecting to outside.

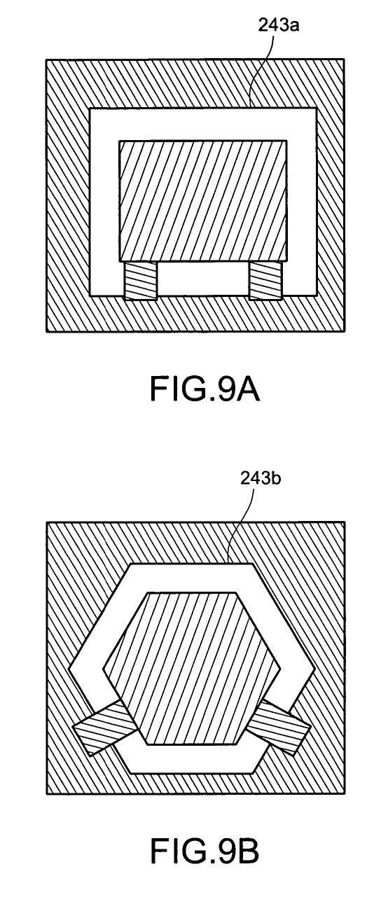

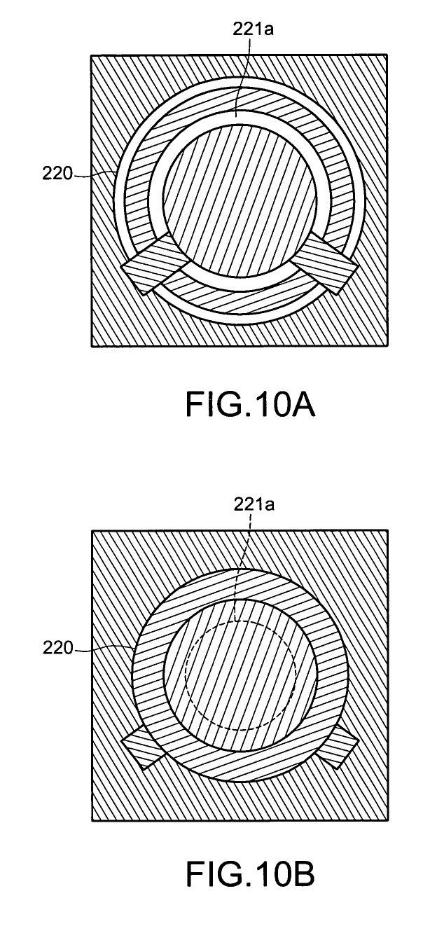

The shape of the channel 243 is not limited to annular, and the shapes of the source 241 and the drain 242 only need to match with that of the channel. The source 241 has the same shape as the island region. This is illustrated in FIGS. 9A and 9B. The island regions defined by the channels 243a, 243b, respectively, are roughly rectangular and polygonal.

The profile of the gate layer 220 corresponds to that of the island region. The area of the gate layer 220 can be either smaller or bigger than the island region. Alternatively, as shown in FIGS. 10A and 10B, the gate layer 220 has an opening region 221a or 221b. Their shapes correspond to the island region. The area of the opening region 221a or 221b can be smaller (FIG. 10A) or bigger (FIG. 10B) than the peninsula region.

In the following, we use the TFT in FIG. 7B as an example to explain the features and advantages of the invention.

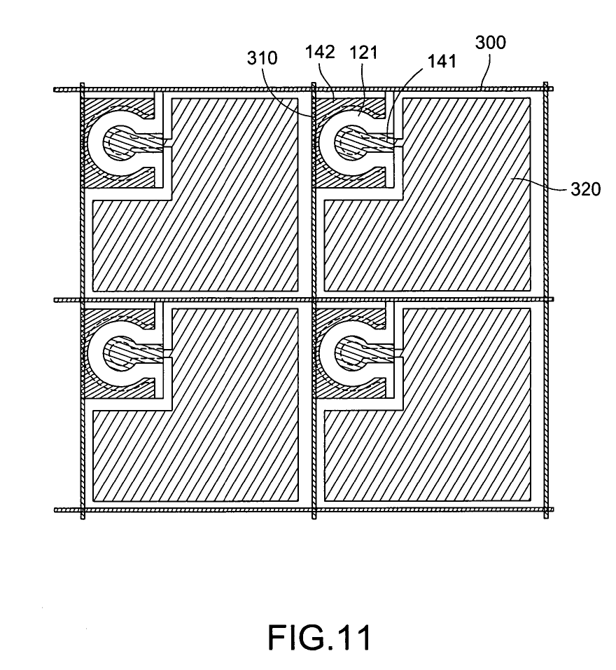

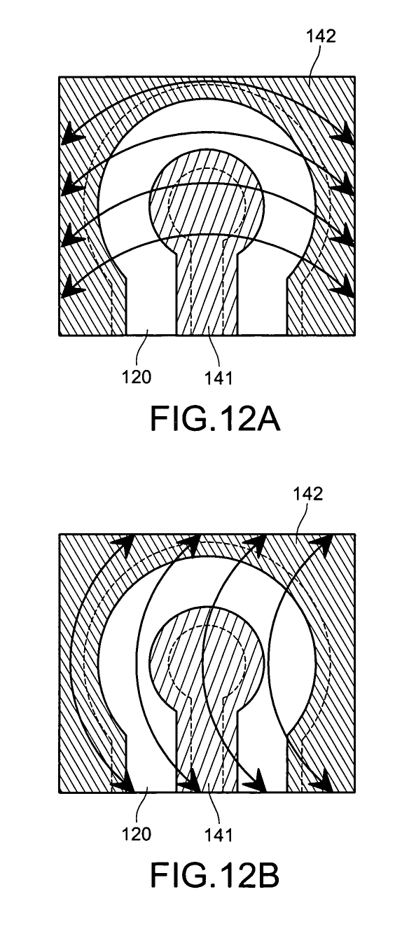

As shown in FIG. 11, when using the TFT as the switch of pixels in a panel, it is formed at a corner of the cross of a gate line 300 and a data line 310. The drain 142 extends from the data line 310. The gate layer 120 extends from the gate line 300. The source 141 is connected to a capacitor 320. In comparison with the conventional TFT, the invention has a smaller area for the same channel aspect ratio. The invention reduces the area occupied by the pixels. In other words, the disclosed TFT has a wider channel for the same total area. This can increase the carrier mobility, so that the charging/discharge speed of the pixel is increased for a better display quality.

Moreover, the channel design in the disclosed TFT enables multiple transmission directions between the source 141 and the drain 142, unlike the conventional TFT that has only one transmission direction with worse electrical performance. In contrast, not only can the TFT in this embodiment reduce the grain boundary trap effect and increase the carrier mobility, current homogeneity, and driving capability, it further has the advantages of reducing field and kink effects.

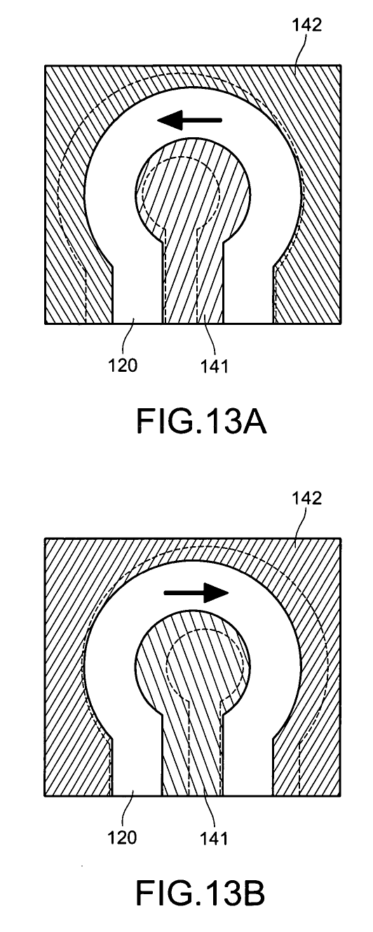

As illustrated in FIGS. 12A and 12B, the TFT according to this embodiment is very flexible. In practice, the disclosed TFT is deflectable in almost all directions. Thus, it is very suitable for a flexible circuit. In comparison with the prior art, the driving current of the TFT is more uniform and therefore more stable.

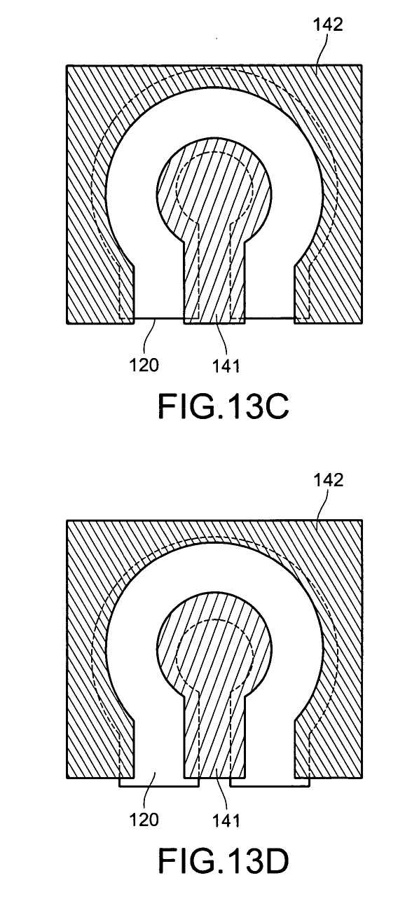

As depicted in FIGS. 13A to 13D, when any deviation happens during the manufacturing process of the TFT (to the left, right, up or down), the symmetric structure of the disclosed TFT renders a smaller deviation. Therefore, the TFT has the same gate-drain capacitance (Cgd) and gate-source capacitance (Cgs). Moreover, the channel aspect ratio is fixed. This increases the yield and lowers the process cost.

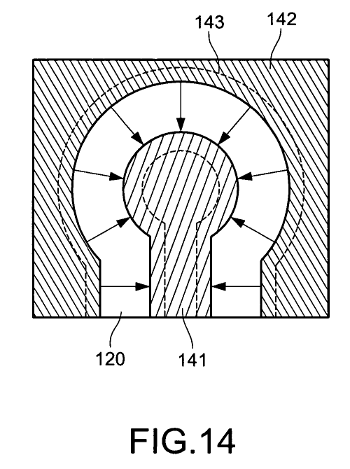

As shown in FIG. 14, due to the symmetric structure of the disclosed TFT, the current is more uniform and thus avoids the hot spot problem. It is not over-heated and has a uniform electric field.

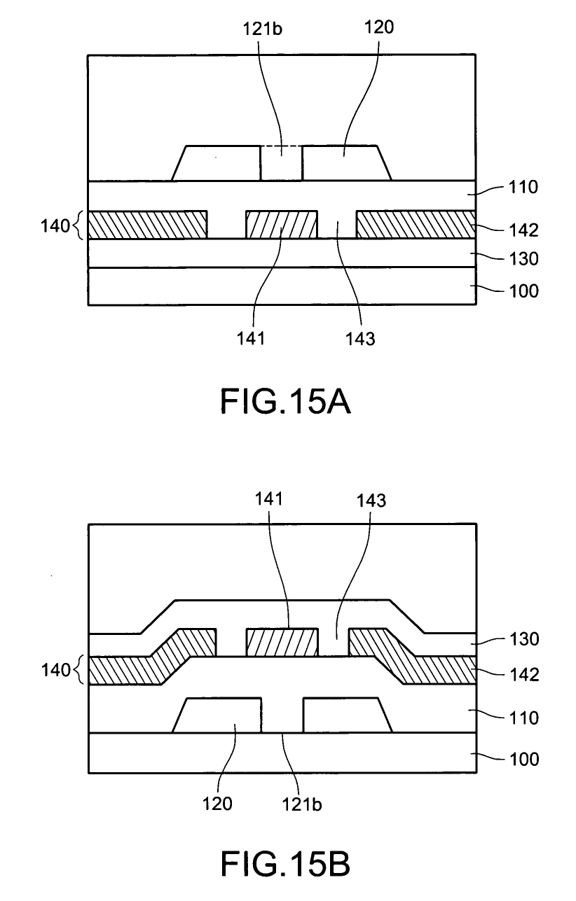

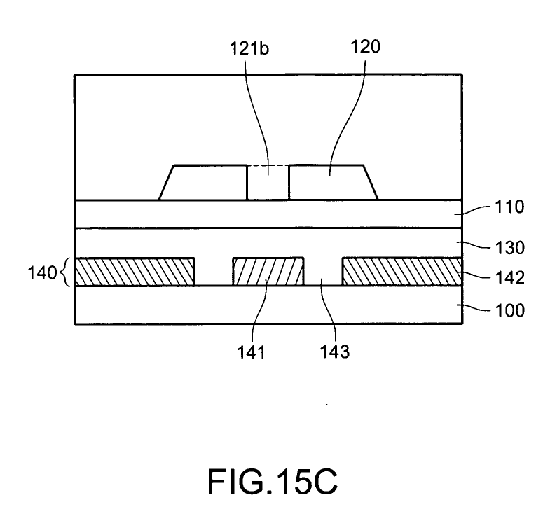

The TFT of the current embodiment can be of the bottom contact type, the top contact type, the bottom gate type, or the top gate type. FIGS. 15A to 15C show the coplanar, inverted coplanar, and staggered TFT's.

Therefore, the invention develops a new special structure for the TFT without changing the process conditions. In addition to obtaining a larger channel aspect ratio within a smaller area, the invention also overcomes the electrical performance problem due to its intrinsic defects. It can be used in the flexible display technology to reduce possible abrupt changes in its electrical properties and to avoid the problem of lower display quality when the TFT experiences deflections in any direction.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A thin-film transistor (TFT), comprising:
a source/drain layer, which includes a source, a drain, and a channel, wherein the channel encloses and defines a peninsula region, and the source and the drain are provided along, respectively, inner and outer sides of the channel so that there are at least two transmission directions between the source and the drain;
a gate layer, which is provided in a vertical direction of the channel corresponding to the source/drain layer;
an insulating layer, which is provided to separate the source/drain layer and the gate layer;
a semiconductor layer, which is used to couple the source/drain layer and the insulating layer; and
a flexible substrate, which is provided for the formation of the source/drain layer, the gate layer, the insulating layer, and the semiconductor layer.

2. The TFT of claim 1, wherein the source is located inside the peninsula region whereas the drain is outside the channel.

3. The TFT of claim 1, wherein the drain is located inside the peninsula region whereas the source is outside the channel.

4. The TFT of claim 1, wherein the profile of the peninsula region is a curve.

5. The TFT of claim 1, wherein the peninsula region has a shape selected from the group consisting of a U shape, a rectangle, and a polygon.

6. The TFT of claim 1, wherein the profile of the gate layer corresponds to the profile of the peninsular region.

7. The TFT of claim 6, wherein the area of the gate layer is smaller than the peninsular region.

8. The TFT of claim 6, wherein the area of the gate layer is greater than the peninsular region.

9. The TFT of claim 6, wherein the gate layer has an opening region.

10. The TFT of claim 9, wherein the shape of the opening region corresponds to the shape of the peninsula region.

11. The TFT of claim 1, wherein the peninsula region has a round head and a neck.

12. The TFT of claim 1, wherein the gate layer is formed on the flexible substrate, the insulating layer is formed on the flexible substrate and covers the gate layer, the source/drain layer is formed on the flexible substrate and covers the insulating layer, and the semiconductor layer is formed on the source/drain layer.

13. The TFT of claim 1, wherein the gate layer is formed on the flexible substrate, the insulating layer is formed on the flexible substrate and covers the gate layer, the semiconductor layer is formed on the flexible substrate and covers the insulating layer, and the source/drain layer is formed on the semiconductor layer.

14. The TFT of claim 1, wherein the semiconductor layer is formed on the flexible substrate, the source/drain layer is formed on the flexible substrate and covers the semiconductor layer, the insulating layer is formed on the flexible substrate and covers the source/drain layer, and the gate layer is formed on the insulating layer.

15. The TFT of claim 1, wherein the source/drain layer is formed on the flexible substrate, the semiconductor layer is formed on the flexible substrate and covers the source/drain layer, the insulating layer is formed on the flexible substrate and covers the semiconductor layer, and the gate layer is formed on the insulating layer.

16. A TFT, comprising:
a source/drain layer, which includes a source, a drain, and a channel, wherein the channel encloses and defines an island region, and the source and the drain are provided along, respectively, the inner and outer sides of the channel so that there are at least two transmission directions between the source and the drain;
a gate layer, which is provided in the vertical direction of the channel corresponding to the source/drain layer;
an insulating layer, which is provided to separate the source/drain layer and the gate layer;
a semiconductor layer, which is used to couple the source/drain layer and the insulating layer; and
a flexible substrate, which is provided for the formation of the source/drain layer, the gate layer, the insulating layer, and the semiconductor layer.

17. The TFT of claim 16, wherein the source is located inside the island region whereas the drain is outside the channel.

18. The TFT of claim 16, wherein the drain is located inside the island region whereas the source is outside the channel.

19. The TFT of claim 16, wherein the profile of the island region is a curve.

20. The TFT of claim 16, wherein the island region has a shape selected from the group consisting of a U shape, a rectangle, and a polygon.

21. The TFT of claim 16, wherein the profile of the gate layer corresponds to the profile of the island region.

22. The TFT of claim 21, wherein the area of the gate layer is smaller than the island region.

23. The TFT of claim 21, wherein the area of the gate layer is greater than the island region.

24. The TFT of claim 21, wherein the gate layer has an opening region.

25. The TFT of claim 24, wherein the shape of the opening region corresponds to the shape of the island region.

26. The TFT of claim 16, wherein the gate layer is formed on the flexible substrate, the insulating layer is formed on the flexible substrate and covers the gate layer, the source/drain layer is formed on the flexible substrate and covers the insulating layer, and the semiconductor layer is formed on the source/drain layer.

27. The TFT of claim 16, wherein the gate layer is formed on the flexible substrate, the insulating layer is formed on the flexible substrate and covers the gate layer, the semiconductor layer is formed on the flexible substrate and covers the insulating layer, and the source/drain layer is formed on the semiconductor layer.

28. The TFT of claim 16, wherein the semiconductor layer is formed on the flexible substrate, the source/drain layer is formed on the flexible substrate and covers the semiconductor layer, the insulating layer is formed on the flexible substrate and covers the source/drain layer, and the gate layer is formed on the insulating layer.

29. The TFT of claim 16, wherein the source/drain layer is formed on the flexible substrate, the semiconductor layer is formed on the flexible substrate and covers the source/drain layer, the insulating layer is formed on the flexible substrate and covers the semiconductor layer, and the gate layer is formed on the insulating layer.
